(19) United States
(12) Patent Application Publication
(10) Pub. No.: US 2025/0214252 A1
(43) Pub. Date: Jul. 3, 2025

(54) TEACHING METHOD, TEACHING PROGRAM, AND SUBSTRATE PROCESSING APPARATUS

(71) Applicant: SEMES CO., LTD., Cheonan-si (KR)

(72) Inventors: Seok Hyeon JEONG, Cheonan-si (KR); Soo Yeon SHIN, Suwon-si (KR); Oh Yeol KWON, Cheonan-si (KR)

(73) Assignee: SEMES CO., LTD., Cheonan-si (KR)

(21) Appl. No.: 18/984,003

(22) Filed: Dec. 17, 2024

(30) Foreign Application Priority Data
Dec. 28, 2023 (KR) 10-2023-0195389

(51) Int. Cl. B25J 9/16; B25J 11/00; B25J 19/02

(52) U.S. Cl. CPC B25J 9/1697; B25J 9/1653; B25J 11/0095; B25J 19/023

(57) ABSTRACT

Disclosed is a teaching method of a transfer robot including a transfer hand, the teaching method including: a first teaching operation of acquiring a first image by photographing, by a vision chamber provided on the transfer robot transferring a substrate, a mark plate attached to a chamber or a frame around the chamber, and adjusting a teaching point of the transfer robot based on the first image; and a second teaching operation of acquiring a second image by photographing, by a substrate-type sensor including an image photographing unit placed on a hand of the transfer robot, a structure in the chamber, and adjusting a teaching point of the transfer robot based on the second image.

### CROSS-REFERENCE TO RELATED APPLICATIONS

This application claims priority to and the benefit of Korean Patent Application No. 10-2023-0195389 filed in the Korean Intellectual Property Office on Dec. 28, 2023, the entire contents of which are incorporated herein by reference.

### TECHNICAL FIELD

The present invention relates to a teaching method, a teaching program, and a substrate processing apparatus.

### BACKGROUND ART

To manufacture semiconductor devices, various processes, such as coating, etching, stripping, cleaning, baking, ion implantation, and drying, are performed on a substrate, such as a wafer. Semiconductor device manufacturing equipment is provided with a plurality of chambers for performing the above processes and a transfer robot for transferring a substrate to each chamber. The transfer robot includes a transfer hand on which the substrate is placed.

In order to properly process the substrate in the above chambers, it is important to transfer the substrate to its correct position in the chamber. The operation of specifying a teaching point, which is the coordinates to which the substrate is transferred into the chamber, is called a teaching operation, and it is necessary to specify an accurate teaching point through the teaching operation so that the transfer robot may transfer the substrate to the correct position.

In general, teaching operations are performed by seating a teaching jig or a substrate such as a wafer on the hand of a transfer robot and manually adjusting the transfer robot by an operator. This method may cause errors depending on the skill level of the operator, and it takes a long time to complete the teaching operation.

### SUMMARY OF THE INVENTION

The present invention has been made in an effort to provide a teaching method, a teaching program, and a substrate processing apparatus that are capable of effectively performing teaching of a transfer robot.

The present invention has also been made in an effort to provide a teaching method, a teaching program, and a substrate processing apparatus that are capable of minimizing the time required for a teaching operation.

The present invention has also been made in an effort to provide a teaching method, a teaching program, and a substrate processing apparatus that are capable of deriving a teaching point of a transfer hand in a chamber without marking separate teaching marks in the chamber.

The problem to be solved by the present invention is not limited to the above-mentioned problems, and the problems not mentioned will be clearly understood by those skilled in the art from the descriptions below.

An exemplary embodiment of the present invention provides a teaching method of a transfer robot including a transfer hand, the teaching method including: a first teaching operation of acquiring a first image by photographing, by a vision chamber provided on the transfer robot transferring a substrate, a mark plate attached to a chamber or a frame around the chamber, and adjusting a teaching point of the transfer robot based on the first image; and a second teaching operation of acquiring a second image by photographing, by a substrate-type sensor including an image photographing unit placed on a hand of the transfer robot, a structure in the chamber, and adjusting a teaching point of the transfer robot based on the second image.

According to the exemplary embodiment, when the vision faces the chamber, a forward-backward direction may be defined as an X direction, a left-right direction may be defined as a Y direction, an up-down direction may be defined as a Z direction, and a circumferential direction centered on the Z direction may be defined as a theta direction, and on the mark plate, a plurality of teaching marks may be marked side by side along the Y direction.

According to the exemplary embodiment, the teaching marks are QR codes.

According to the exemplary embodiment, the first teaching operation may include: a mark photographing operation of acquiring, by the vision, the first image; and a first error calculation operation of recognizing the teaching marks and deriving at least one of a direction in which the teaching marks are listed, a length of the mark plate, and an offset between the mark plate and a first reference point from the first image, and calculating an error between a position of the transfer hand at the time when the transfer robot acquires the first image and a position of the transfer hand when the transfer hand transfers the substrate to a regular position based on a result of the derivation.

According to the exemplary embodiment, the teaching method may further include a first hand position adjustment operation of adjusting a position and/or an angle of the transfer hand of the transfer robot by an error in the Y direction, the Z direction, and/or the theta direction calculated in the first error calculation operation.

According to the exemplary embodiment, the second teaching operation may include: a hand loading operation of loading the transfer hand into a processing space of the chamber in a state where the transfer hand supports the substrate-type sensor; and a port photographing operation of photographing, by the substrate-type sensor loaded into the processing space by the transfer hand, a circular fluid port to acquire the second image.

According to the exemplary embodiment, the port photographing operation may include photographing, by the substrate-type sensor, the fluid port in the state where the substrate-type sensor is placed on the transfer hand.

According to the exemplary embodiment, the second teaching operation may include a second error calculation operation of deriving at least one of a radius of the fluid port and an offset between a center point of the fluid port and a second reference point from the second image, and calculating an error between a position of the transfer hand at the time when the substrate-type sensor acquires the second image and a position of the transfer hand when the transfer hand transfers the substrate to a regular position based on a result of the derivation.

According to the exemplary embodiment, when the vision faces the chamber, a forward-backward direction may be defined as an X direction, a left-right direction may be defined as a Y direction, an up-down direction may be defined as a Z direction, and a circumferential direction centered on the Z direction may be defined as a theta direction, and the teaching method may further include a second hand position adjustment operation of adjusting a position and/or an angle of the transfer hand of the transfer robot by an error in the X direction, the Y direction, the Z direction, and/or the theta direction calculated in the second error calculation operation.

Another exemplary embodiment of the present invention provides a teaching program stored in a storage medium for deriving a teaching point of a transfer robot included in a substrate processing apparatus, the teaching program including: generating an instruction for acquiring, by a vision provided on the transfer robot, a first image by photographing a mark plate attached to a chamber or a frame around the chamber, wherein the mark plate is marked with a plurality of teaching marks; deriving at least one of a direction in which the teaching marks are arranged, a length of the mark plate, and a first offset between the mark plate and a center point of the first image from the first image; and calculating an error in a teaching position of a hand of the transfer robot through at least one of the direction in which the teaching marks are arranged, the length of the mark plate, and the first offset.

According to the exemplary embodiment, the teaching program may perform generating an instruction for primarily adjusting the position of the transfer hand of the transfer robot in at least one direction among a Z direction, which is an up-down direction, a Y direction, which is a horizontal direction perpendicular to the Z direction, and a theta direction, which is a circumferential direction centered on the Z direction, based on the calculated error.

According to the exemplary embodiment, the teaching program may perform, after primarily adjusting the position of the transfer hand, storing coordinates of the transfer hand as a primary teaching point.

According to the exemplary embodiment, the teaching program may perform: generating an instruction for loading the transfer hand into a processing space of the chamber in a state where the transfer hand supports a substrate-type sensor after the position of the transfer hand is primarily adjusted; and generating an instruction for the substrate-type sensor to photograph a fluid port of the chamber to acquire a second image.

According to the exemplary embodiment, the teaching program may perform deriving a radius of the fluid port and a second offset between a center of the fluid port and a center point of the second image from the second image.

According to the exemplary embodiment, the teaching program may perform generating an instruction for secondarily adjusting the position of the transfer hand in the Y direction, the Z direction, the theta direction, and an X direction perpendicular to the Y direction and the Z direction based on the radius of the fluid port and the second offset.

According to the exemplary embodiment, the teaching program may perform after the position of the transfer hand is secondarily adjusted, storing coordinates of the transfer hand as a secondary teaching point.

Still another exemplary embodiment of the present invention provides an apparatus for processing a substrate, the apparatus including: a plurality of chambers configured to process a substrate, wherein the chamber provides a processing space in which the substrate is processed, and includes a port configured to supply a processing fluid to the processing space; a frame configured to provide placement spaces in which the plurality of chambers are arranged; a teaching plate attached to the frame and having a plurality of teaching marks marked; a transfer robot configured to transfer a substrate; and a controller configured to control the chamber and the transfer robot, in which the transfer robot includes: a transfer hand on which a substrate and a substrate-type sensor is selectively placed; and a vision positioned on a top side of the transfer hand and photographing the teaching plate, and the controller may adjust a teaching point of the transfer hand based on a first image acquired by photographing the teaching plate and a second image acquired by photographing the port.

According to the exemplary embodiment, the first image may be acquired by the vision, and the second image may be acquired by the substrate-type sensor placed on the transfer hand.

According to the exemplary embodiment, the teaching marks marked on the teaching plate may be QR codes.

According to the exemplary embodiment, the port may be a supply port supplying the processing fluid to a top surface of the substrate and have a circular shape

According to the exemplary embodiment of the present invention, it is possible to effectively perform teaching of the transfer robot.

According to the exemplary embodiment of the present invention, it is possible to minimize the time required for the teaching operation.

According to the exemplary embodiment of the present invention, it is possible to derive the teaching point of the transfer hand in the chamber without marking separate teaching marks in the chamber.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram illustrating a substrate processing apparatus according to an exemplary embodiment of the present invention.

FIG. 2 is a diagram illustrating a transfer robot of FIG. 1.

FIG. 3 is a diagram illustrating a view of a liquid treatment chamber of FIG. 1.

FIG. 4 is a diagram illustrating a drying chamber of FIG. 1.

FIG. 5 is a diagram schematically illustrating a substrate-type sensor used in a teaching method of the present invention.

FIG. 6 is a flow chart of the teaching method of the present invention.

FIG. 7 is a diagram illustrating a position where a mark plate photographed in a first teaching operation of FIG. 6 is installed.

FIG. 8 is a diagram illustrating the appearance of the mark plate of FIG. 7.

FIG. 9 is a diagram illustrating a first image acquired by a vision before the first teaching operation is completed.

FIG. 10 is a diagram illustrating the first image acquired by the vision after the first teaching operation is completed.

FIG. 11 is a diagram illustrating a second image acquired by the substrate-type sensor before the second teaching operation is completed.

FIG. 12 is a diagram illustrating the second image acquired by the substrate-type sensor after the second teaching operation is completed.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, a manufacturing method, a substrate processing method, and a substrate processing apparatus according to an exemplary embodiment of the present invention will be described in detail. The manufacturing method may be a method of manufacturing a semiconductor device. The substrate processing method may be processes corresponding to some of various processes required to manufacture the semiconductor device. Further, a substrate processing apparatus may be an apparatus for implementing the above substrate processing method for processing a substrate W, such as a wafer. Further, the substrate processing apparatus may correspond to a semiconductor device manufacturing apparatus capable of performing processes corresponding to some of the various processes required to manufacture the semiconductor devices described above.

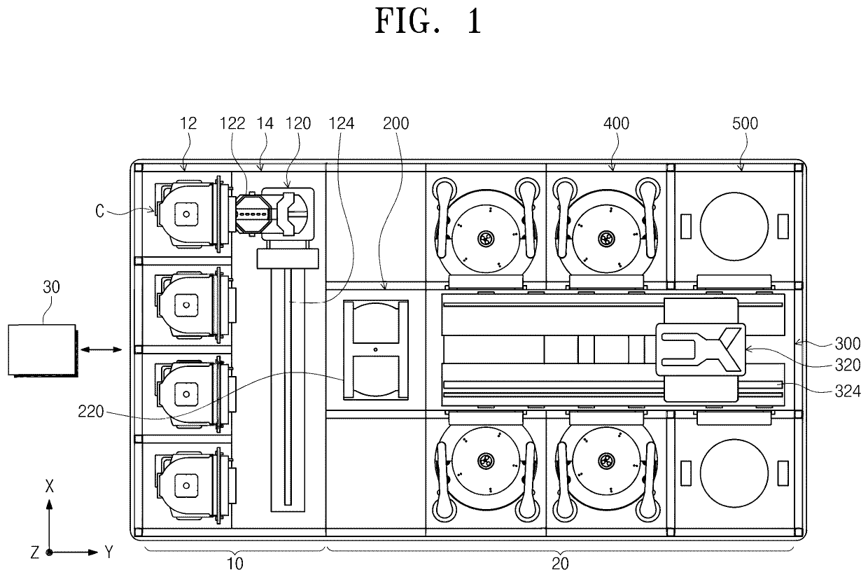

Hereinafter, an exemplary embodiment of the present invention will be described in detail with reference to FIGS. 1 to 11.

FIG. 1 is a diagram illustrating a substrate processing apparatus according to an exemplary embodiment of the present invention.

Referring to FIG. 1, a substrate processing apparatus includes an index module 10, a processing module 20, and a controller 30. When viewed from above, the index module 10 and the processing module 20 are disposed along one direction. Hereinafter, a direction in which the index module 10 and the processing module 20 are disposed is referred to as a Y direction, a direction perpendicular to the Y direction when viewed from above is referred to as an X direction, and a direction perpendicular to both the X and Y directions, and the direction up and down is referred to as a Z direction. Furthermore, when a vision CAM of the transfer robot 320 looks at the liquid treatment chamber 400 or the drying chamber 500, the X direction may be a forward-backward direction, the Y direction may be a left-to-right direction, and the Z direction may be an up-down direction.

The index module 10 transfers the substrate W from the container C in which the substrate W is accommodated to the processing module 20, and accommodates the substrate W that has been completely treated in the processing module 20 in the container C. A longitudinal direction of the index module 10 is provided in the X direction. The index module 10 includes a load port 12 and an index frame 14. Based on the index frame 14, the load port 12 is located at a side opposite to the processing module 20. The container C in which the substrates W are accommodated is placed in the load port 12. A plurality of load ports 12 may be provided, and the plurality of load ports 12 may be disposed along the X direction.

As the container C, an airtight container, such as a Front Open Unified Pod (FOUP), may be used. The container C may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is provided in the X direction is provided in the index frame 14, and the index robot 120 may be provided to be movable on the guide rail 124. The index robot 120 includes a hand 122 on which the substrate W is placed, and the hand 122 may be provided to be movable forwardly and backwardly, rotatable about the Z direction and movable along the Z direction. A plurality of hands 122 are provided to be spaced apart in the vertical direction, and the hands 122 may move forwardly and backwardly independently of each other.

The processing module 20 includes a buffer unit 200, a transfer chamber 300, a liquid treatment chamber 400, and a drying chamber 500. The buffer unit 200 provides a space in which the substrate W loaded into the processing module 20 and the substrate W unloaded from the processing module 20 stay temporarily. The liquid treatment chamber 400 performs a liquid treating process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treatment chamber 400, and the drying chamber 500.

The buffer unit 200 includes a plurality of buffers 220 on which the substrate W is placed. The buffers 220 may be disposed to be spaced apart from each other along the Z direction. The buffer 220 may be a substrate holder that supports the underside of the substrate W. The buffer 220 may be provided in the form of a support shelf that supports the underside of the substrate W.

A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

The transfer chamber 300 may be provided with its longitudinal direction in the Y direction. The buffer unit 200 may be disposed between the index module 10 and the transfer chamber 300. The liquid treatment chamber 400 and the drying chamber 500 may be disposed on the side portion of the transfer chamber 300. The liquid treatment chamber 400 and the transfer chamber 300 may be disposed along the X direction. The drying chamber 500 and the transfer chamber 300 may be disposed along the X direction. The buffer unit 200 may be located at one end of the transfer chamber 300.

According to the example, the liquid treatment chambers 400 are disposed on both sides of transfer chamber 300, and the drying chambers 500 are disposed on both sides of the transfer chamber 300, and the liquid treatment chambers 400 may be disposed closer to the buffer unit 200 than the drying chambers 500. At one side of the transfer chamber 300, the liquid treatment chambers 400 may be provided in an arrangement of A×B (each of A and B is 1 or a natural larger than 1) in the Y direction X and the Z direction. Further, at one side of the transfer chamber 300, the drying chambers 500 may be provided in number of C×D (each of C and D is 1 or a natural number larger than 1) in the Y direction and the Z direction. Unlike the above, only the liquid treatment chambers 400 may be provided on one side of the transfer chamber 300, and only the drying chambers 500 may be provided on the other side of the transfer chamber 300.

The transfer chamber 300 includes a transfer robot 320. Within the transfer chamber 300, the transfer rail 324 of which a longitudinal direction is provided in the Y direction may be provided, and the transfer robot 320 may be provided to be movable on the transfer rail 324.

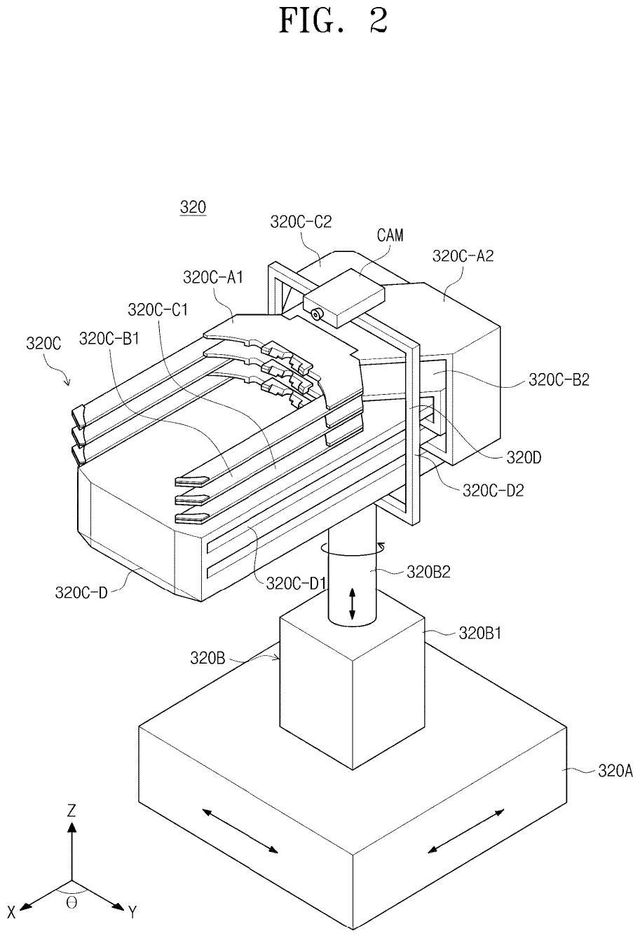

FIG. 2 is a diagram illustrating the transfer robot of FIG. 1. The transfer robot 320 may include a rail traveling part 320A, a hand drive part 320B, and a hand part 320C. The rail traveling part 320A may be slidably provided on the transfer rail 324 described above. The rail traveling part 320A may include a drive motor for traveling along the transfer rail 324.

The hand drive part 320B may rotate the hand part 320C. The hand drive part 320B may move the hand part 320C in the Z direction. The hand drive part 320B may include a drive box 320B1 and a drive shaft 320B2. The drive box 320B1 may include a drive device for rotating the drive shaft 320B2, or for moving the drive shaft 320B2 in an up and down direction. The drive shaft 320B2 may rotate the hand part 320C 360 degrees. That is, the hand part 320C may change its position along the Y direction by the rail traveling part 320A, change its position along the theta (0) direction, which is a circumferential direction centered on the Z direction, by the hand drive part 320B, and change its height along the Z direction.

The hand part 320C may include a first hand 320C-A1, a first hand movable body 320C-A2, a second hand 320C-B1, a second hand movable body 320C-B2, a third hand 320C-C1, a third hand movable body 320C-C2, and a sliding body 320C-D.

The first hand 320C-A1 may be configured to support the underside of the substrate W. The first hand 320C-A1 may be installed at a higher height than the second hand 320C-B1 and the third hand 320C-C1. The first hand 320C-A1 may be coupled with the first hand movable body 320C-A2. The first hand movable body 320C-A2 may be slidably installed in a second sliding groove 320C-D2 formed in the sliding body 320C-D. The first hand 320C-A1 may be configured to be moveable forward and backward by movement of the first hand movable body 320C-A2.

The second hand 320C-B1 may be configured to support the underside of the substrate W. The second hand 320C-B1 may be installed at a higher height than the third hand 320C-C1 and at a lower height than the first hand 320C-A1. The second hand 320C-B1 may be coupled to the second hand movable body 320C-B2. The second hand movable body 320C-B2 may be slidably installed in a first sliding groove 320C-D1 formed in the sliding body 320C-D. The second hand 320C-B1 may be configured to be moveable forward and backward by movement of the second hand movable body 320C-B2.

The third hand 320C-C1 may be configured to support the underside of the substrate W. The third hand 320C-C1 may be installed at a lower height than the first hand 320C-A1 and the second hand 320C-B1. The third hand 320C-C1 may be coupled with the third hand movable body 320C-C2. The third hand movable body 320C-C2 may be slidably installed in the first sliding groove 320C-D1 or the second sliding groove 320C-D2 formed in the sliding body 320C-D on a side opposite to the first and second hand movable bodies. In contrast, the third hand movable body 320C-C2 may be slidably installed on the opposite side from the first and second hand movable bodies in a third sliding groove (not illustrated), which is a groove different from the first sliding groove 320C-D1 and the second sliding groove 320C-D2 formed in the sliding body 320C-D. The third hand 320C-C1 may be configured to be moveable forward and backward by movement of the third hand movable body 320C-C2.

Additionally, the transfer robot 320 may be equipped with a vision CAM. The vision CAM may be a device for acquiring a first image IM1 when performing the teaching method described herein. The vision CAM may include a camera and a lighting. The vision CAM may be installed on a vision fixation frame 320D. The vision fixation frame 320D may be secured to the sliding body 320C-D. The vision CAM may be fixed to the sliding body 320C-D and may be moved along the Y direction, the Z direction, and the theta direction with the transfer hands 320C-A1, 320C-B1, and 320C-C1.

Referring again to FIG. 1, the controller 30 may control the substrate processing apparatus.

The controller 30 may generate commands to control configurations of the substrate processing apparatus described herein, and/or perform operations for image processing, recognizing objects in the image, adjusting teaching points, and the like necessary to perform the teaching methods described herein.

The control unit 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing processing performed by the substrate processing apparatus under the control of a process controller, a teaching program for adjusting/deriving a teaching point of the transfer robot, and a program, i.e. a treatment recipe, for executing processing to each component according to various data and processing conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

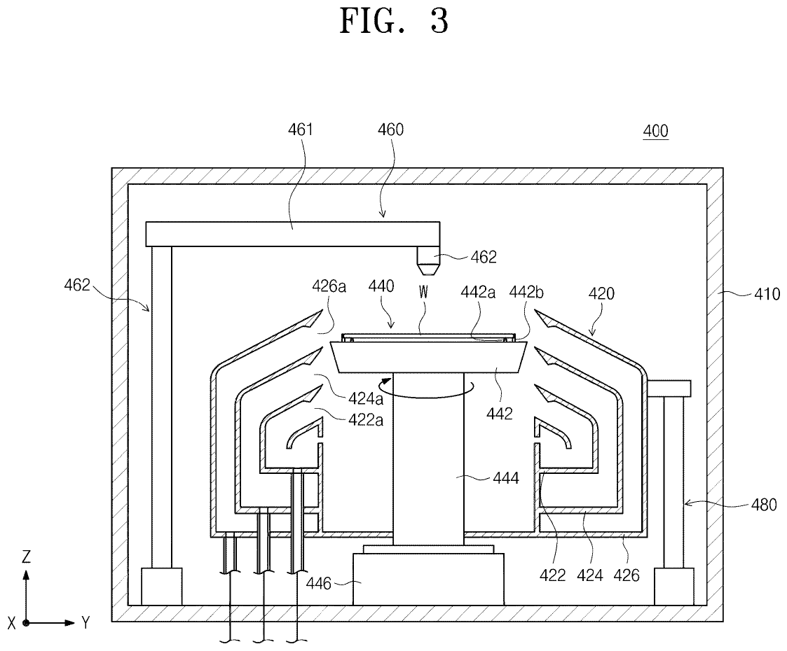

FIG. 3 is a diagram illustrating a view of the liquid treatment chamber of FIG. 1.

Referring to FIG. 3, the liquid treatment chamber 400 includes a housing 410, a treatment container 420, a support unit 440, a liquid supply unit 460, and a lifting unit 480.

The housing 410 may have an interior space where the substrate W is processed. The housing 410 may have a generally hexahedral shape. For example, the housing 410 may have a cuboidal shape. Additionally, the housing 410 may have an opening (not illustrated) through which the substrate W is loaded or unloaded. Additionally, the housing 410 may be equipped with a door (not illustrated) that selectively opens and closes the opening.

The treatment container 430 may have a cylindrical shape with an open top. The processing container 420 may provide a processing space where the substrate W is processed. The support unit 440 supports the substrate W in the processing space. The liquid supply unit 460 supplies the treatment solution onto the substrate W supported on the support unit 440. The treatment solution may be provided in a plurality of types and may be supplied sequentially onto the substrate W. The lifting unit 480 adjusts the relative height between the treatment container 420 and the substrate W placed on the support unit 440.

In one example, the treatment container 420 has a plurality of recovery containers 422, 424, and 426. Each of the recovery containers 422, 424, and 426 has a recovery space of recovering the liquid used for the processing of the substrate. Each of the recovery containers 422, 424, and 426 is provided with a shape that surrounds the support unit 440. As the liquid treating process proceeds, the treatment solution scattered by the rotation of the substrate W enters the recovery space through inlets 422a, 424a, and 426a of the respective recovery containers 422, 424, and 426. In one example, the treatment container 420 has the first recovery container 422, the second recovery container 424, and the third recovery container 426. The first recovery container 422 is disposed to surround the support unit 440, the second recovery container 424 is disposed to surround the first recovery container 422, and the third recovery container 426 is disposed to surround the second recovery container 424.

The second inlet 424a, which introduces liquid into the second recovery container 424, may be positioned above a top side of the first inlet 422a, which introduces liquid into the first recovery container 422, and the third inlet 426a, which introduces liquid into the third recovery container 426, may be positioned above a top side of the second inlet 424a.

The support unit 440 includes a support plate 442 and a driving shaft 444. An upper surface of the support plate 442 may be provided in a generally circular shape, and may have a diameter larger than a diameter of the substrate W. The edge region of a top surface of the support plate 442 may be provided with a support pin 442a that supports the rear surface of the substrate W. The support pin 442a is provided with a top end protruding from the support plate 442 such that the substrate W is spaced a certain distance from the support plate 442.

A chuck pin 442b is provided to an edge of the top surface of the support plate 442. The chuck pin 442b may be provided at the outer side of the support pin 442a. The chuck pin 442b is provided to protrude upwardly from the support plate 442, and chucks the lateral portion of the substrate W so that the substrate W is not separated from the support unit 440 when the substrate W is rotated. A drive shaft 444 is driven by a driver 446 and is coupled to the center of the lower surface of the support plate 442 and rotates the support plate 442 about its central axis.

The liquid supply unit 460 may supply a treatment solution to the substrate W. The liquid supply unit 460 may include an arm 461, a nozzle 462, and a driver 463. The nozzle 462 may be installed at one end of the bar-shaped arm 461. The driver 463 may be configured in the form of a rotating shaft with a rotational axis in the Z direction and may be coupled to the other end of the arm 461. The driver 463 may pivot the arm 461 by rotating about a rotational axis in the Z direction. Accordingly, the position of the nozzle 462 installed at one end of the arm 461 may be changed.

The nozzle 462 may supply a treatment solution to the substrate W. The treatment solution may be a chemical, a rinse solution, or an organic solvent. The chemical may be a chemical having the nature of strong acid or strong base. Further, the rinse solution may be pure water. Furthermore, the organic solvent may be isopropyl alcohol (IPA).

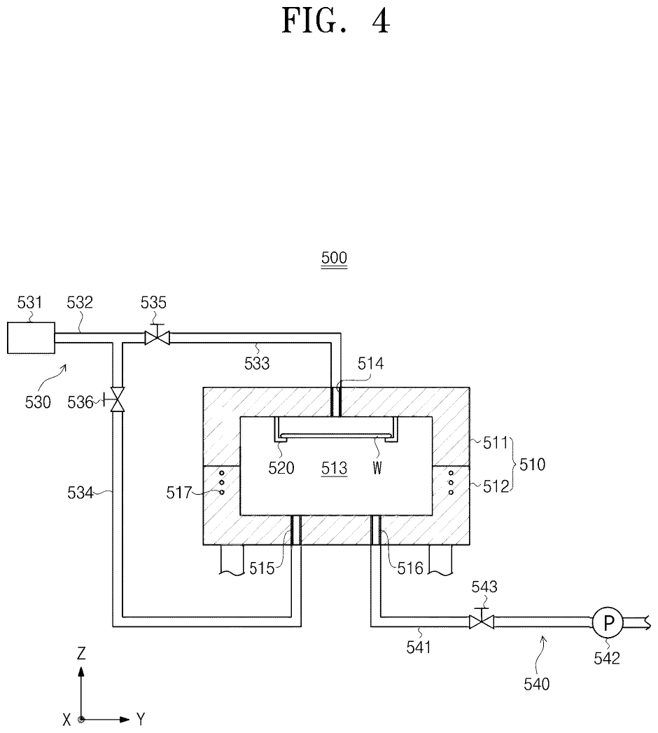

Only one nozzle 462 is illustrated in FIG. 4, but the liquid supply unit 460 may include a plurality of nozzles 462, each of which may be configured to supply a different type of treatment solution. For example, one of the nozzles 462 may supply a chemical, another of the nozzles 462 may supply a rinse solution, and yet another of the nozzles 462 may supply an organic solvent. Further, the controller 30 may control the liquid supply unit 460 to supply a rinse solution from one of the nozzles 462 to the substrate W, followed by supplying an organic solvent from another one of the nozzles 462. Accordingly, the rinse solution supplied on the substrate W may be replaced with an organic solvent having a small surface tension.

The lifting unit 480 may move the treatment container 420 in an upward or downward direction. The relative height between the treatment container 420 and the substrate W changes as the treatment container 420 is moved up and down. The lifting unit 480 may include a power generating device, such as a motor, pneumatic cylinder, or hydraulic cylinder. The lifting unit 480 may adjust the height of the treatment container 420 to differentiate the recovery containers 422, 424, and 426 for recovering the treatment solution depending on the type of liquid supplied to the substrate W.

Alternatively, as described above, the treatment container 420 may be fixedly installed and the support plate 442 may be configured to be movable in an up and down direction.

FIG. 4 is a diagram illustrating the drying chamber of FIG. 1.

Referring to FIG. 4, the drying chamber 500 may include a body 510, a support member 520, a fluid supply unit 530, and a fluid exhaust unit 540.

The body 510 may provide a processing space 513 where the substrate W is processed. The body 510 may include a first body 511 and a second body 512. At least one of the first body 511 and the second body 512 may have a shape that is recessed in a direction away from the other of the first body 511 and the second body 512. The first body 511 and the second body 512 may be combined with each other to define the processing space 513. The first body 511 and the second body 512 may be formed of a material that may withstand the high pressure conditions of the processing space 513. For example, the first body 511 and the second body 512 may be formed from a material, such as a metal, such as aluminum. The first body 511 may be an upper body positioned at the top, and the second body 512 may be a lower body positioned at the bottom.

A position of at least one of the first body 511 and the second body 512 may be changed by a driver (not illustrated). For example, the position of the first body 511 may be fixed and the second body 512 may be configured to be movable along the Z direction. The driver may be any one of an air cylinder, a pneumatic cylinder, a motor, and a magnetic levitation actuator.

The driver may move the second body 512 between an open position and a close position. When the second body 512 is in the open position, the processing space 513 may be open to the outside. When the second body 512 is in the close position, the first body 511 and the second body 512 may be combined with each other to provide the sealed processing space 513.

The first body 511 may be provided with a first supply port 514. The first supply port 514 may be connected to the first fluid supply line 533, which will be described later, to supply treatment fluid to the processing space 513. An outlet of the first supply port 514 faces an upper region of the processing space 513 and may face the upper surface of the substrate W resting on the support member 520. The first supply port 514 may be formed on the first body 511 itself, or may be provided as a separate supply pipe inserted into the first body 511.

The second body 512 may be provided with a second supply port 515. The second supply port 515 may be connected to a second fluid supply line 534, which will be described later, to supply treatment fluid to the processing space 513. The outlet of the second supply port 515 may face a lower region of the processing space 513. Similar to the first supply port 514, the second supply port 515 may be formed in the second body 512 itself, or may be provided as a separate supply pipe inserted into the second body 512.

Additionally, the second body 512 may be provided with an exhaust port 516. The exhaust port 516 may be connected to the exhaust line 541, which will be described later, to exhaust the atmosphere of the processing space 513. The exhaust port 516 may the exhaust treatment fluid, such as carbon dioxide, supplied to the processing space 513 to the outside of the processing space 513 to reduce the pressure in the processing space 513. The exhaust port 516 may be provided in parallel with the second supply port 515. Similar to the first supply port 514 and second supply port 515, the exhaust port 516 may be formed in the second body 512 itself, or may be provided as a separate supply pipe inserted into the second body 512.

The first supply port 514, the second supply port 515, and the exhaust port 516 may be referred to as fluid ports.

In the example described above, the present invention has been described based on the case where the first supply port 514 is provided on the first body 511 and the second supply port 515 and exhaust port 516 are provided on the second body 512 as an example, but the present invention is not limited thereto. For example, the first supply port 514, the second supply port 515, and the exhaust port 516 may all be provided on the first body 511, or all may be provided on the second body 512.

The body 510 may be provided with a heater 517. The heater 517 may be installed while being buried in the interior of the first body 511 and/or the second body 512. The heater 517 may be a resistive heater. Alternatively, the heater 517 may be variously modified to any known device that generates heat. The heater 517 may increase the temperature of the processing space 513. The heater 517 may maintain the temperature of the processing space 513 at a set temperature. Here, the set temperature may be set to a temperature above a critical temperature that allows the state of the treatment fluid to remain supercritical.

The support member 528 may support the substrate W. The support member 520 may be configured to support the substrate W in the processing space 513 provided by the body 510.

The support member 520 may be configured to support a bottom surface of the substrate W. The support member 520 may be configured to support the bottom edge region of the substrate W. The support member 520 may be fixedly installed on the underside of the first body 511. The support members 520 may be provided in pairs. Each support member 520 may extend in a downward direction from the first body 511 toward the second body 512 and may have a laterally bent shape at the end to support the bottom surface of the substrate W.

When the area of contact between the substrate W and the support member 520 is large, the risk of damage, such as scratches, to the bottom surface of the substrate W increases; however, the support member 520 may be configured to support only the edge region of the bottom surface of the substrate W, thereby minimizing the area of contact with the bottom surface of the substrate W.

The fluid supply unit 530 may supply the treatment fluid to the processing space 513. The treatment fluid may be drying gas that removes any residual treatment solution on the substrate W. For example, the treatment fluid may be carbon dioxide gas. The treatment fluid may also be converted to a supercritical state and supplied to the processing space 513. Alternatively, the treatment fluid may be supplied to the processing space 513 in a gaseous state and phase converted to the supercritical state in the processing space 513.

The fluid supply unit 530 may include a fluid supply source 531, a main supply line 532, a first fluid supply line 533, a second fluid supply line 534, a first supply valve 535, and a second supply valve 536.

The supply lines 532, 533, and 534 may be equipped with line heaters (not illustrated) to heat the treatment fluid flowing in the supply lines 532, 533, and 534.

The fluid supply source 531 may store and supply a treatment fluid. The fluid supply source 531 may be a fluid storage tank capable of storing and supplying the treatment fluid. The fluid supply source 531 may be configured to store and supply carbon dioxide.

The fluid supply source 531 may be connected to one end of the main supply line 532. The other end of the main supply line 532 may be branched into a first fluid supply line 533 and a second fluid supply line 534. The first fluid supply line 533 may be connected to the first supply port 514 described above. The second fluid supply line 534 may be connected to the second supply port 515. The first fluid supply line 533 may be configured to supply treatment fluid to an upper region of the processing space 513, and the second fluid supply line 534 may be configured to supply treatment fluid to a lower region of the processing space 513.

The first supply valve 535 may be installed in the first fluid supply line 533. The first supply valve 535 may be provided as an auto valve that receives a control signal from the controller 30 to allow or block the flow of the treatment fluid in the first fluid supply line 533.

Similarly, the second fluid supply line 534 may be provided with the second supply valve 536. The second supply valve 536 may be provided as an auto-valve that receives a control signal from the controller 30 to allow or block the flow of the treatment fluid in the second fluid supply line 534.

The fluid exhaust unit 540 may control the atmosphere of the processing space 513. The fluid exhaust unit 540 may exhaust the treatment fluid supplied to the processing space 513 to the outside of the drying chamber 500. The fluid exhaust unit 540 may include a fluid exhaust line 541, an exhaust device 542, and an exhaust valve 543.

The fluid exhaust line 541 may be connected with the exhaust port 516 described above. The exhaust valve 543 may be installed in the fluid exhaust line 541, and the exhaust valve 543 may be provided as an auto valve that receives a control signal from the controller 30 to allow or block the flow of the treatment fluid in the exhaust line 541.

An exhaust device 542 may be coupled to the exhaust line 541. The exhaust device 542 may be a pressure reducing device that depressurizes the processing space 513. For example, the exhaust device 542 may be a pump. However, without limitation, the exhaust device 542 may be variously modified to any known device that is capable of providing depressurization to the processing space 513 through the exhaust line 541 and the exhaust port 516.

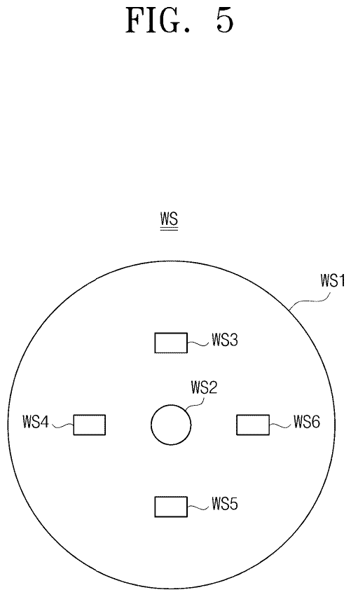

FIG. 5 is a diagram schematically illustrating a substrate-type sensor used in a teaching method of the present invention.

Referring to FIG. 5, the substrate-type sensor WS may have the same or similar shape as the substrate W. The substrate-type sensor WS may be transferred by the transfer robot 320. The substrate-type sensor WS may be supported on the transfer hand of the transfer robot 320.

The substrate-type sensor WS may include a plate WS1, an image photographing unit WS2, a processor WS3, a memory WS4, a battery WS5, and a communication unit WS6. The plate WS1 may be a body on which the image photographing unit WS2, the processor WS3, the memory WS4, the battery WS5, and the communication unit WS6 are installed. The plate WS1 may have the same or similar shape as the substrate W described above.

The image photographing unit WS2 may be a camera. The image photographing unit WS2 may be a member for acquiring a second image IM2 described hereinafter. The image photographing unit WS2 may further include a lighting. The image photographing unit WS2 may be mounted on a top surface of the plate WS1 to photograph images in an upward direction.

The processor WS3 may generate instructions to control the image photographing unit WS2. The processor WS3 may also perform image processing on the second image IM2 acquired by the image photographing unit WS2. The second image IM2 processed by the processor WS3 may be stored in the memory WS4, which may be a memory medium such as RAM or ROM, or may be transmitted to the controller 30 via the communication unit WS6.

The communication unit WS6 may transmit data processed by the processor WS3, such as a LAN card, and/or data stored in the memory WS4 to the controller 30. In addition, the communication unit WS6 may receive instructions from the controller 30.

The battery WS5 may apply the power required for the processor WS3, the memory WS4, and the communication unit WS6 to operate. The image photographing unit WS2, the processor WS3, the memory WS4, the battery WS5, and the communication unit WS6 may be electrically connected to each other.

In the following, a teaching method according to an exemplary embodiment of the present invention will be described in detail.

To perform the teaching method described below, the controller 30 may generate instructions to control configurations of the substrate processing apparatus, such as the transfer robot 320 and the drying chamber 500, and may transmit and receive data/instructions to and from the substrate-type sensor WS. Further, the teaching method may be automatically implemented by a program stored in a memory medium of the controller 30. Further, the teaching method may be a method for deriving a teaching point, which is the coordinates of a position at which the transfer hand of the transfer robot 320 transfers the substrate W.

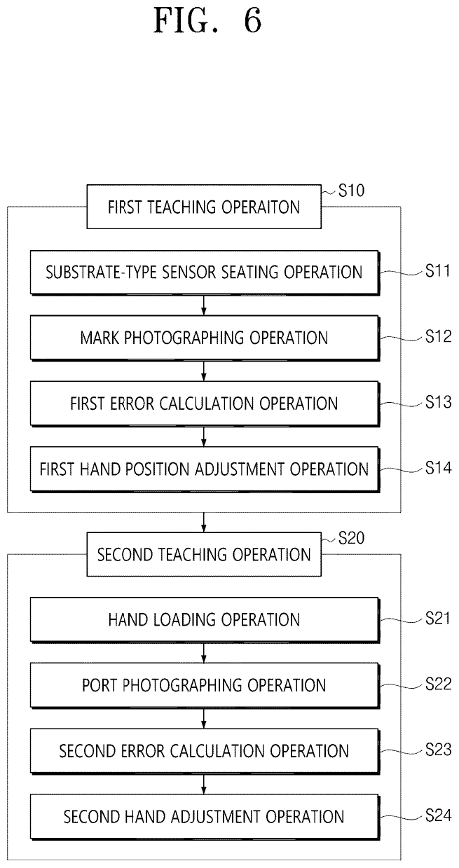

FIG. 6 is a flow chart of the teaching method of the present invention. Referring to FIG. 6, the teaching method according to the exemplary embodiment of the present invention may include a first teaching operation S10, and a second teaching operation S20.

The first teaching operation S10 may be an operation of teaching a position of the chamber, specifically a position of the drying chamber 500, with respect to the transfer robot 320. The first teaching operation S10 may include a substrate-type sensor seating operation S11, a mark photographing operation S12, a first error calculation operation S13, and a first hand position adjustment operation S14.

In the substrate-type sensor seating operation S11, the substrate-type sensor WS may be seated on the transfer hand of the transfer robot 320. The transfer hand may be any of the first to third hands 320C-A1, 320C-B1, and 320C-C1 described above.

In the mark photographing operation S12, the mark plate MP is photographed in the state where the substrate-type sensor is seated on the transfer hand of the transfer robot 320. In the mark photographing operation S12, the transfer robot 320 may move to a position close to a chamber, such as the drying chamber 500, for performing a teaching operation based on a primary temporary teaching point. The primary temporary teaching point may be temporarily specified coordinates that are derived from the design of the substrate processing apparatus. After the transfer robot 320 has moved to the position close to the drying chamber 500 where teaching is to be performed based on the primary temporary teaching point, the vision CAM of the transfer robot 320 may photograph the mark plate MP.

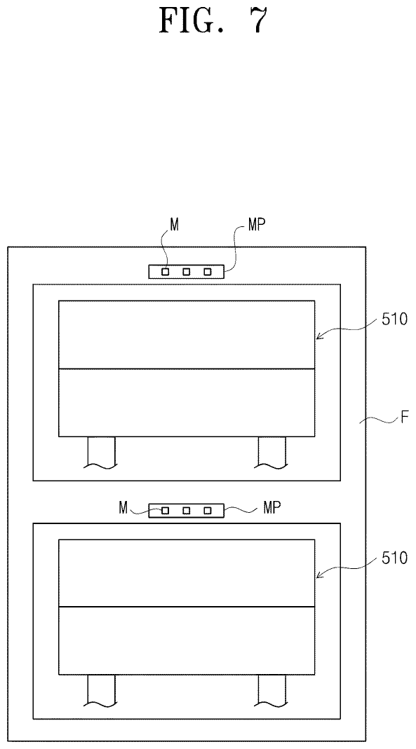

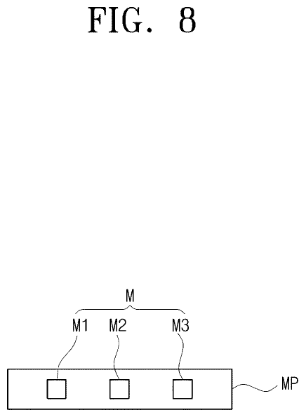

FIG. 7 is a diagram illustrating a position where the mark plate photographed in the first teaching operation of FIG. 6 is installed, and FIG. 8 is a diagram illustrating the appearance of the mark plate of FIG. 7. FIG. 7 may be a view of the transfer robot 320 looking at the drying chamber 500 along the X direction.

Referring to FIGS. 7 and 8, the substrate processing apparatus may include a frame F. The frame F may provide placement spaces in which the bodies 510 of the drying chamber 500 described above may be disposed. In each of the placement spaces, each of the bodies 510 of the drying chambers 500 may be disposed.

The frame F may be equipped with the mark plate MP. Since the mark plate MP is provided for the teaching operation, it is very important that its position does not change. Since the second body 512 described above is moved repeatedly in the Z direction, and the processing space 513 is maintained at a very high pressure while the process is being performed, it is highly likely that the position of the body 510 itself will change. Therefore, the mark plate MP may be installed on the frame F to minimize the change in position of the mark plate MP during the process.

The mark plate MP may be marked with a plurality of teaching marks M. It should be understood that marking the mark plate MP with the teaching marks M includes not only the mark plate MP itself being machined to mark the teaching marks M, but also the teaching marks M being separately printed and affixed to the mark plate MP. The plurality of teaching marks M may be QR codes. The teaching mark M that is the QR code may include information about the drying chamber 500. Additionally, the plurality of teaching marks M may be arranged side-by-side along the Y direction.

The plurality of teaching marks M may include a first mark M1, a second mark M2, and a third mark M3. The first mark M1, the second mark M2, and the third mark M3 may be QR codes of different shapes. The first mark M1, the second mark M2, and the third mark M3 may contain information about different drying chambers 500.

In the mark photographing operation S12, the mark plate MP may be photographed to acquire a first image IM1.

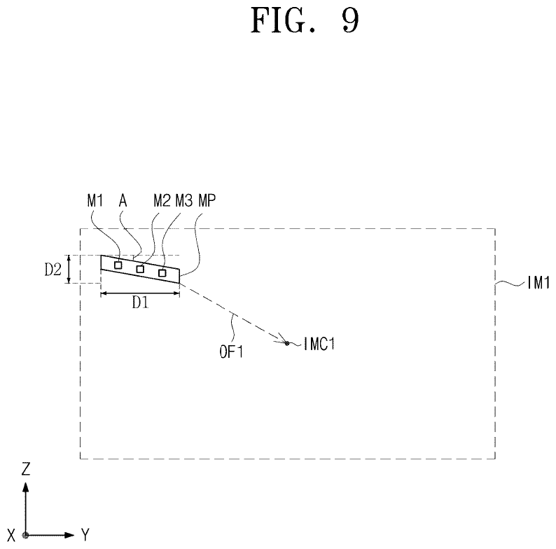

FIG. 9 is a diagram illustrating the first image acquired by the vision before the first teaching operation is completed.

Referring to FIGS. 6 and 9, at the time the transfer robot 320 acquires the first image IM1, the transfer hand of the transfer robot 320 may have moved based on the primary temporary teaching point. When the primary temporary teaching point of the transfer robot 320 corresponds to a regular position, a center point (IMC1, an example of a first reference point) of the first image IM1 acquired by the vision CAM and a center point of the mark plate MP may coincide with each other. In FIG. 9, since the center point of the mark plate MP and the center point IMC1 of the first image do not coincide with each other, the primary temporary teaching point may be the to be in a state in need of adjustment.

In the first error calculation operation S13, the controller 30 may calculate an error for adjusting the primary temporary teaching point of the transfer robot 320 from the first image IM1 acquired by the vision CAM.

Specifically, the first error calculation operation S13 may include calculating an error between a position of the transfer hand at the time when the transfer robot 320 acquires the first image IM1 (the position before the adjustment of the primary teaching point) and a position of the transfer hand when the transfer hand transfers the substrate W to the regular position (the position after the adjustment of the primary teaching point).

The teaching plate MP may be marked with a plurality of teaching marks M. The vision CAM may detect the plurality of teaching marks M. The controller 30 may derive an angle A by which the teaching plate MP is tilted based on the direction in which the teaching marks M are listed in the first image IM1. Further, the controller 30 may compare a left-to-right length D1 and a top-to-bottom length D2 of the mark plate MP derived in the first image IM1 with an actual left-to-right length and an actual top-to-bottom length of the mark plate MP, and derive a deviation therefrom. Further, a first offset OF1 from the mark plate MP and the center point IMC1 of the first image IM1 may be derived.

Based on the angle A at which the mark plate MP is tilted as described above, the deviation of the length of the mark plate MP in the image from the actual length, and the first offset OF1, an error between the position at the time when the transfer hand of the transfer robot 320 transfers the substrate W to the regular position and the position when the transfer hand acquires the first image IMC1 may be calculated.

The calculated error may be an error in the Y direction, an error in the Z direction, or an error in the theta direction.

In the first hand position adjustment operation S14, the transfer hand of the transfer robot 320 may be adjusted in position and angle by the error in the Y direction, the error in the Z direction, and the error in the theta direction based on the error value calculated in the first error calculation operation S13. When the first hand position adjustment operation S14 is completed, the transfer hand of the transfer robot 320 may be positioned at the regular position. The coordinates of the transfer hand of the transfer robot 320 positioned at the regular position may be memorized in the controller 30 as a primary teaching point.

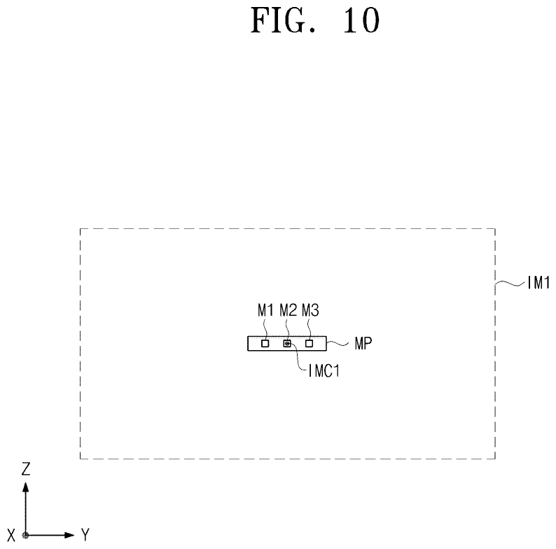

FIG. 10 is a diagram illustrating the first image acquired by the vision after the first teaching operation is completed.

When the mark plate MP is photographed the vision CAM after the first teaching operation S10 is completed, the center of the mark plate MP may coincide with the center point IMC1 of the first image IM1.

When the first teaching operation S10 is completed, the processing space 513 may be opened. In this case, the transfer hand of the transfer robot 320 may move downwardly by a set distance. Thereafter, a hand loading operation S21 described later may be performed.

Referring again to FIG. 6, the second teaching operation S20 may be performed after the first teaching operation S10. The second teaching operation S20 may be an operation of teaching a position in which the transfer hand of the transfer robot 320 places the substrate W down on the support member 520.

The second teaching operation S20 may include a hand loading operation S21, a port photographing operation S22, a second error calculation operation S23, and a second hand adjustment operation S24.

In the hand loading operation S21, the transfer hand may be loaded into the processing space 513. The transfer hand may be loaded into the processing space 513 while supporting the substrate-type sensor WS. The transfer hand may be loaded into the processing space 513 according to a secondary temporary teaching point. The secondary temporary teaching point may be a teaching point temporarily derived from the design of the substrate processing apparatus, similar to the primary temporary teaching point described above.

The port photographing operation S22 may be an operation in which the substrate-type sensor WS placed on the transfer hand photographs a structure of the drying chamber 500, such as the first supply port 514. In the port photographing operation S22, the substrate-type sensor WS may photograph the first supply port 514 in the state where the substrate-type sensor WS is placed on the transfer hand. In the port photographing operation S22, a second image IM2 may be acquired. The first supply port 514 is a circular fluid port. Therefore, the image acquired by photographing, by the substrate-type sensor WS, the first supply port 514 may also have a circular shape.

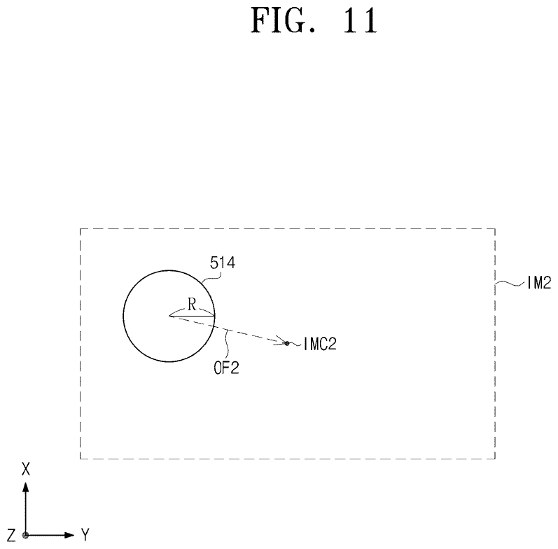

FIG. 11 is a diagram illustrating the second image acquired by the substrate-type sensor before the second teaching operation is completed.

Referring to FIGS. 6 and 11, in the second error calculation operation S23, from the second image IM2, a radius R of the first supply port 514 and a second offset OF2 between a center point of the first supply port 514 and a center point of the second image IM2 (IMC2, an example of a second reference point) may be derived. Then, an error between the position when the transfer hand transfers the substrate W to the regular position and the position of the transfer hand when the substrate-type sensor WS acquires the second image IM2 may be derived.

The above error may be calculated from the radius R of the first supply port 514 and the second offset OF2. For example, the radius R of the first supply port 515 in the second image IM2 is compared with a radius memorized in advance (for example, the radius of the first supply port 514 photographed by the substrate-type sensor WS placed on the transfer hand when the transfer hand transfers the substrate W to the regular position). Further, when the radius R is smaller than the pre-memorized radius, it is determined that the height in the Z-direction of the transfer hand is low, and when the radius R is larger than the pre-memorized radius, it is determined that the height in the Z-direction of the transfer hand is high. In addition, the error of the transfer hand in the X-direction and Y-direction, and if necessary, in the theta direction, may be calculated according to the second offset OF2.

In the second hand position adjustment operation S24, the position and/or angle of the transfer hand may be adjusted by the error in the X-direction, Y-direction, Z-direction, and theta direction calculated in the second error calculation operation S23. After the second hand position adjustment operation S24 is performed, the transfer hand of the transfer robot 320 may be positioned at the regular position. The coordinates of the transfer hand of the transfer robot 320 positioned at the regular position may be memorized in the controller 30 as a secondary teaching point.

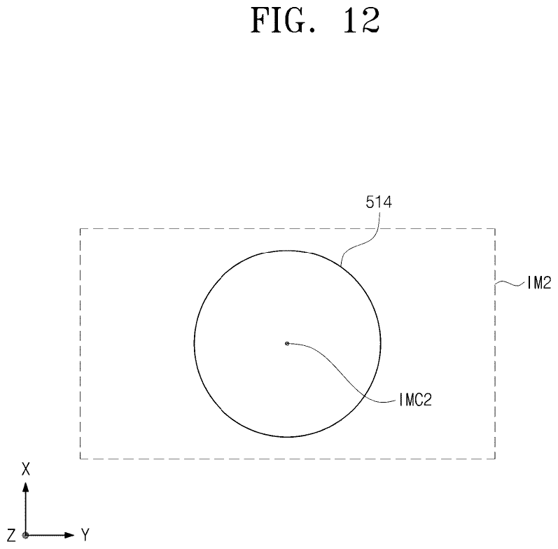

FIG. 12 is a diagram illustrating the second image acquired by the substrate-type sensor after the second teaching operation is completed.

After the second teaching operation S20 is completed, when the first supply port 514 is photographed by the substrate-type sensor WS, the radius of the first supply port 514 is the same as the pre-memorized radius, and the center point of the first supply port 514 may coincide with the center point IMC2 of the second image IM2. The substrate-type sensor WS photographs the first supply port 514 having a cylindrical shape. When the first supply port 514 is photographed, since its shape is circular, the radius and the center point of the first supply port 514 may be acquired relatively easily.

In addition, when viewed from above, the center of the first supply port 514 coincides with the center of the substrate W placed on the support member 520. Therefore, when the secondary teaching point is derived through the first supply port 514, there is an advantage in that it is possible to teach relatively accurately the transfer position of the substrate W even without marking/installing a separate teaching mark in the drying chamber 500.

In the above-described example, the present invention has been described based on the case where the substrate-type sensor WS photographs the first supply port 514 as an example, but it is not limited thereto. For example, the substrate-type sensor WS may be provided in the chamber and may photograph a circular structure having a center that coincides with the center of the substrate W positioned at the regular position, thereby performing the second teaching operation S20.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A teaching method of a transfer robot including a transfer hand, the teaching method comprising:
a first teaching operation of acquiring a first image by photographing, by a vision chamber provided on the transfer robot transferring a substrate, a mark plate attached to a chamber or a frame around the chamber, and adjusting a teaching point of the transfer robot based on the first image; and
a second teaching operation of acquiring a second image by photographing, by a substrate-type sensor including an image photographing unit placed on a hand of the transfer robot, a structure in the chamber, and adjusting a teaching point of the transfer robot based on the second image.

2. The teaching method of claim 1, wherein when the vision faces the chamber, a forward-backward direction is defined as an X direction, a left-right direction is defined as a Y direction, an up-down direction is defined as a Z direction, and a circumferential direction centered on the Z direction is defined as a theta direction, and
on the mark plate, a plurality of teaching marks is marked side by side along the Y direction.

3. The teaching method of claim 2, wherein the teaching marks are QR codes.

4. The teaching method of claim 2, wherein the first teaching operation includes:
a mark photographing operation of acquiring, by the vision, the first image; and
a first error calculation operation of recognizing the teaching marks and deriving at least one of a direction in which the teaching marks are listed, a length of the mark plate, and an offset between the mark plate and a first reference point from the first image, and calculating an error between a position of the transfer hand at the time when the transfer robot acquires the first image and a position of the transfer hand when the transfer hand transfers the substrate to a regular position based on a result of the derivation.

5. The teaching method of claim 4, further comprising:
a first hand position adjustment operation of adjusting a position and/or an angle of the transfer hand of the transfer robot by an error in the Y direction, the Z direction, and/or the theta direction calculated in the first error calculation operation.

6. The teaching method of claim 1, wherein the second teaching operation includes:
a hand loading operation of loading the transfer hand into a processing space of the chamber in a state where the transfer hand supports the substrate-type sensor; and
a port photographing operation of photographing, by the substrate-type sensor loaded into the processing space by the transfer hand, a circular fluid port to acquire the second image.

7. The teaching method device of claim 6, wherein the port photographing operation includes photographing, by the substrate-type sensor, the fluid port in the state where the substrate-type sensor is placed on the transfer hand.

8. The teaching method of claim 7, wherein the second teaching operation includes a second error calculation operation of deriving at least one of a radius of the fluid port and an offset between a center point of the fluid port and a second reference point from the second image, and calculating an error between a position of the transfer hand at the time when the substrate-type sensor acquires the second image and a position of the transfer hand when the transfer hand transfers the substrate to a regular position based on a result of the derivation.

9. The teaching method of claim 8, wherein when the vision faces the chamber, a forward-backward direction is defined as an X direction, a left-right direction is defined as a Y direction, an up-down direction is defined as a Z direction, and a circumferential direction centered on the Z direction is defined as a theta direction, and
the teaching method further comprises a second hand position adjustment operation of adjusting a position and/or an angle of the transfer hand of the transfer robot by an error in the X direction, the Y direction, the Z direction, and/or the theta direction calculated in the second error calculation operation.

10. A teaching program stored in a storage medium for deriving a teaching point of a transfer robot included in a substrate processing apparatus, the teaching program performing:
generating an instruction for acquiring, by a vision provided on the transfer robot, a first image by photographing a mark plate attached to a chamber or a frame around the chamber, wherein the mark plate is marked with a plurality of teaching marks;
deriving at least one of a direction in which the teaching marks are arranged, a length of the mark plate, and a first offset between the mark plate and a center point of the first image from the first image; and
calculating an error in a teaching position of a hand of the transfer robot through at least one of the direction in which the teaching marks are arranged, the length of the mark plate, and the first offset.

11. The teaching program of claim 10, wherein the teaching program performs generating an instruction for primarily adjusting the position of the transfer hand of the transfer robot in at least one direction among a Z direction, which is an up-down direction, a Y direction, which is a horizontal direction perpendicular to the Z direction, and a theta direction, which is a circumferential direction centered on the Z direction, based on the calculated error.

12. The teaching program of claim 11, wherein the teaching program performs, after primarily adjusting the position of the transfer hand, storing coordinates of the transfer hand as a primary teaching point.

13. The teaching program of claim 11, wherein the teaching program performs generating an instruction for loading the transfer hand into a processing space of the chamber in a state where the transfer hand supports a substrate-type sensor after the position of the transfer hand is primarily adjusted; and
generating an instruction for the substrate-type sensor to photograph a fluid port of the chamber to acquire a second image.

14. The teaching program of claim 13, wherein the teaching program performs deriving a radius of the fluid port and a second offset between a center of the fluid port and a center point of the second image from the second image.

15. The teaching program of claim 14, wherein the teaching program performs generating an instruction for secondarily adjusting the position of the transfer hand in the Y direction, the Z direction, the theta direction, and an X direction perpendicular to the Y direction and the Z direction based on the radius of the fluid port and the second offset.

16. The teaching program of claim 15, wherein the teaching program performs, after the position of the transfer hand is secondarily adjusted, storing coordinates of the transfer hand as a secondary teaching point.

17. (canceled)

18. (canceled)

19. (canceled)

20. (canceled)
